(19) United States
(12) Patent Application Publication
(10) Pub. No.: US 2004/0058068 A1
(43) Pub. Date: Mar. 25, 2004

(54) Method for vapor-deposit and x-ray luminophore on a carrier

(76) Inventors: Manfred Fuchs, Nurnberg (DE); Erich Hell, Gingen (DE); Peter Rohrer, Bubenreuth (DE)

Correspondence Address: SCHIFF HARDIN, LLP, PATENT DEPARTMENT, 6600 SEARS TOWER, CHICAGO, IL, 60606-6473, US

(21) Appl. No.: 10/630,165

(22) Filed: Jul. 30, 2003

(30) Foreign Application Priority Data
Jul. 31, 2002 (DE) 102 35 051.5

(51) Int. Cl. C23C 16/00

(52) U.S. Cl. 427/248.1

(57) ABSTRACT

A method forms a vapor-deposit layer of needle-shaped x-ray luminophore containing at least one alkali metal doped with europium on a carrier. The method includes placing a mixture of Eu₃O₄Hal and at least one alkali halogenide in a molybdenum vaporizer, heating the mixture to simultaneously vaporize the mixture and to deposit it on a carrier, wherein Hal is at least one halogenide from a group consisting of F, Cl, Br and I. The ratio of the Eu concentration of the alkali halogenide layer in the proximity of the substrate to the Eu concentration of the alkali halogenide layer in the proximity of the surface can preferably be reproduced with a factor of 0.4 to 1.2, and preferably between 0.6 and 0.8.

### BACKGROUND OF THE INVENTION

The present invention is directed to a method for vapor-depositing a layer of a needle-shaped x-ray luminophore with at least one alkali metal on a carrier.

An article by Paul J. R. Leblans et al entitled “New Needle-crystalline CR Detector” from Proc. of SPIE, Vol. 4320 (2001), pages 59-67 describes how cesium bromide doped with europium has developed in recent years as a storage luminophore and successfully tested with corresponding scanners for computed radiography (CR). It is important that the dopant (europium) is present in a bivalent form, since the luminophore then shows the desired blue emission.

It is known from WO 01/03156 A1 that EuBr₂, EuCI₂, EuI₂ and EuF₂ can be employed as bivalent doping substances. However, these materials can be difficult to produce and also are not available to specialized chemical enterprises. Another disadvantage of these materials is that they hydrate easily. Such hydrated materials cannot be practically vaporized, since water separates upon heating of the material in the vaporizer and the vaporization material is spun out from the vaporizer.

WO 01/03156 A1 also teaches that trivalent europium halogenides (fluoride, chloride, bromide and iodide) can also be employed for producing CsBr:Eu²⁺. However, it is known from the literature that the trivalent europium halogenides are also subject to hydratization, as is described in an article by Haschke et al entitled “The Preparation and Some Properties of Europium Bromides and Hydrated Bromides” from J. Inorg. Nucl. Chem., 1970, Vol. 32, pp. 2153-2158. In addition, EuBr₃ already decomposes at low temperatures, such as 390° C., into EuBr₂ and Br₂, so that a harmful bromine to both man and material would arise at high heat, as can be learned from Gmelins Handbuch, Vol. 39, page 71.

It is also known from WO 01/03156 that trivalent europium oxyhalogenides (fluoride, chloride, bromide and iodide) can also be employed for the production of CsBr:Eu²⁺. A great disadvantage of this employed EuOBr is that the doping material is composed of trivalent europium and the desired bivalent europium does not occur until vaporization either together with the cesium bromide or separately therefrom. Bromine arises as a result of this chemical reaction, which bromine is dangerous not only for people, but rather also acts extremely aggressively against the materials used in the vaporization system. In particular, the components not made from stainless steel will be attacked by the bromine, the vapor deposition shuttle and the pump system, such as the turbo pump and forepump, will be coated with an oxide layer or, respectively, the bromine will decompose the employed forepump oil.

Another disadvantage of the EuOBr is that the europium concentration is very different, both within a layer in proximity to the substrate or surface and from vapor deposition to vapor deposition, in particular when EuOBr is vaporized from the reservoir. Vaporizing from the reservoir means that EuOBr is filled once and only CsBr is replenished for each vapor deposition.

As can be learned from the depiction, the layer comprises less europium in the middle at the beginning of the vapor deposition. In contrast, toward the end of the vapor deposition, more europium in the layer is in the middle.

The principal reason for the pronounced spreading of the europium values are the processes that occur upon vaporization of the EuOBr, which processes are described in an article by Haschke et al entitled “Preparation and Vaporization Thermodynamics of Europium Oxide Bromides” from Journal of the American Chemical Society, Jul. 29, 1970, page 4550-4553.

4 EuOBr (solid)→Eu₃O₄Br (solid)+EuBr₂ (vap.)+Br (vap.)

3 Eu₃O₄Br (solid)→4 Eu₂O₃ (solid)+EuBr₂ (vap.)+Br (vap.)

for a total reaction of:

12 EuOBr (solid)→4 Eu₂O₃ (solid)+4 EuBr₂ (vap.)+2 Br (vap.)

As can be recognized, thermal decomposition reaction comprises two steps. Such a two-step process generally has different reaction speeds and, thus, different vaporization rates will occur. Dependent on how much of which constituent is still present in the vaporization residue of the successive vapor depositions, the resulting Eu concentrations in the condensed CsBr:Eu layer will vary greatly. In addition to residues of CsBr, both EuOBr and Eu₃O₄Br can be detected, however, no EuBr₂ can be detected. Given successive vapor depositions, this proportion changes very greatly.

The large fluctuations of the Eu concentrations are probably also one reason why the Eu concentration of a CsBr:Eu has a broad range in WO 01/03156 A1 with 10⁻³ mol % to 5 mol % and is not precisely specified. It is well known that very high dopant concentrations in luminophore layers have a negative effect on the afterglow behavior of the luminophore. For example, CsBr doped with EuBr₂ from EuBr₃ is shown in Table 1, in which a noticeable undesired afterglow is already detectable at 0.3 mol % europium (which is 3000 ppm).

TABLE 1
luminescence from Eu-doping of CsBr with EuBr₃

| concentra- | | | | | decay | |
|---|---|---|---|---|---|---|
| tion | decay | pro- | decay | pro- | time | Pro- |
| (mol %) | time (ns) | portion | time (μs) | portion | (ms) | portion |
| 0.01 | 800 | 100 | — | 0 | — | 0 |
| 0.1 | 800 | 100 | — | 0 | — | 0 |
| 0.3 | 575 | 44 | 20 | 34 | 2.6 | 23 |
| 1 | 650 | 53 | 8.7 | 36 | 1.2 | 11 |
| 3 | 630 | 90 | 18 | 10 | — | 0 |

On the other hand, lower Eu concentrations of around 100 ppm in the CsBr:Eu layer have a noticeable reduced light yield in comparison to layers of greater than 150 ppm.

Another disadvantage of EuOBr is that it absorbs water in the air, as can be learned from Gmelins Handbuch, Vol. 39, page 82. Storage of vaporization materials is therefore not possible, since, otherwise, the above-cited problems specified for EuBr₂ occurs upon vaporization.

### SUMMARY OF THE INVENTION

The object of the present invention is to form a method of the above-cited type that can be easily implemented, in the process of which no hygroscopic materials occur and a uniform x-ray luminophore is achieved.

The object is thereby inventively achieved in that at least one Eu₃O₄ halogenide is vaporized simultaneously with at least one alkali halogenide and vapor deposited on the carrier, so that a uniform Eu doping of the alkali halogenides is achieved.

It has proven to be advantageous when europium(III) oxyhalogenide is vaporized in a vaporizer made from molybdenum.

In an advantageous manner, the ratio between the Eu concentration of the alkali halogenide layer in the proximity to the substrate to the Eu concentration of the alkali halogenide layer in the proximity to the surface can be reproduced in the co-vaporization of the alkali halogenide with the europium(III)-oxyhalogenide between a factor of 0.4 and 1.2, and preferably in a range of between 0.6 to 0.8.

Eu₃O₄Hal can be inventively employed as the europium(III)-oxyhalogenide, wherein Hal is at least one halogenide from a group consisting of F, Cl, Br and I.

Eu₃O₄Br is preferably used as the vaporization material for the desired europium doping in bivalent form for alkali halogenides. Upon vaporization, this europium oxybromide decays into Eu₂O₃, EuBr₂ and Br₂. Eu₃O₄Br is not hygroscopic and can, thus, be easily vaporized and stored in air for weeks at a time, for example, see Gmelins Handbuch, Vol. 39, page 85.

It has also proven to be of further advantage that the release of EuBr₂, given the production of Eu₃O₄Br during the vapor deposition process, is much more uniform than in the case of the production from the previously used EuOBr. This is well-founded in that the reaction process, given EuOBr is a two-stage process with, respectively, the end product EuBr₂, while the thermal decay process given Eu₃O₄Br is only over one stage and continuously occurs. In addition to Eu₃O₄Br, only Eu₂O₃ is detectable in the residue of the vaporization materials after the vapor deposition process.

Given the co-vaporization of CsBr with Eu₃O₄Br, the ratio of the Eu concentration of the CsBr layer in the proximity of the substrate to the Eu concentration of the CsBr layer in the proximity to the surface can be reproduced between a factor of 0.4 and 1.2, and typically with a factor between 0.6 to 0.8.

Since bromine is generated upon vaporization of trivalent europium bonds, thus, also with Eu₃O₄Br, vaporizers made from graphite, iron, etc., are not appropriate. For the co-vaporization of the alkali halogenide (for example, CsBr) with Eu₃O₄Br, molybdenum has risen to the forefront, since the bromides are thermally stable and do not co-vaporize which, for example, can lead to staining of the layer in the case of tantalum or cobalt. The molybdenum bromides are visible as a black coating on the surface of the vaporizer.

What has been specified here for CsBr is also valid for other alkali halogenides, for example CsCl, CsI, RbBr, RbCl, RbI. Instead of Eu₃O₄Br, the corresponding fluorides, chlorides and iodides can also be employed.

In an advantageous manner, the alkali halogenide can comprise an alkali metal from the group consisting of Na, K, Rb and Cs and at lest one halogenide from the group consisting of F, Cl, Br and I.

According to the inventive method, an x-ray luminophore arises according to the following formula:

AB/C:EuD,E

wherein A is an alkali metal from the group consisting of Na, K, Rb and Cs; B and C are at least on halogenide from the group consisting of F, Cl, Br and I, wherein the group C can equal 0 and D and E are at least one halogenide from the group consisting of F, Cl, Br and I, wherein A, D and/or E can be equal.

The carrier preferably forms a storage luminophore plate with the layer of the needle-shaped x-ray luminophore.

The replacement of EuOBr with Eu₃O₄Br leads to more uniform doping with bivalent europium given co-vaporization with alkali halogenides. This is true both within the layer and from layer to layer. By using a molybdenum vaporizer, it is thereby prevented that bromides can co-vaporize and stain the CsBr:Eu layer.

### DESCRIPTION OF THE PREFERRED EMBODIMENTS

The principles of the present invention are particularly useful when incorporated in a method to form a storage luminophore plate having a layer of needle-shaped x-ray luminophores comprising an alkali halogenide doped with bivalent europium.

The method includes providing a molybdenum vaporizer, introducing a mixture of at least one europium(III) oxyhalogenide and at least one alkali halogenide into the vaporizer and heating the mixture to simultaneously vaporize the mixture to vapor-deposit the alkali metal halogenide doped with bivalent europium. As pointed out hereinabove, the x-ray luminophore occurs from the following formula:

AB/C:EuD,E

wherein A is alkali metal from the group consisting of Na, K, Rb and Cs; B and C are at least one halogenide from the group consisting of F, Cl, Br and I, wherein group C can equal 0 and groups D and E are at least one halogenide from the group consisting of F, Cl, Br and I, and wherein A, D and/or E can be equal.

In the following, only one example is given per all possible combinations between absorber and dopant. The principal reference is CsBr:Eu; only the material constituents are given as a result and not the stoichiometry.

### EXAMPLE a

Initially, 0.25 g of Eu₃O₄Br and 249.75 g CsBr powder are filled into a vaporizer made from molybdenum. The materials are simultaneously vaporized, producing a bivalent Eu doping of the CsBr without discoloration of the layer. This CsBr:EuBr₂ layer, which is needle-shaped due to the vapor deposition, can be used in an x-ray excitation as the luminophore layer (fluorescence) or a storage luminophore layer (electron/hole pairs that can be read out) for medical technology or destruction-free material testing. This is an example of an Eu-oxybromide and cesium bromide with a low Eu concentration.

### EXAMPLE b

Initially, 150 g Eu₃O₄Br and 350 g CsBr powder are filled into a vaporizer made from molybdenum. The materials are simultaneously vaporized to produce a white CsBr:EuBr₂ luminophore layer or storage luminophore layer. This is an example of an Eu-oxybromide and cesium bromide with high Eu concentration.

### EXAMPLE c

Initially, 10 g Eu₃O₄Br and 290 g CsBr powder are filled into a molybdenum vaporizer. The materials are heated to simultaneously vaporize, producing a white CsBr:EuBr₂ luminophore layer or storage luminophore layer. This is an example of an Eu-oxybromide and cesium bromide.

### EXAMPLE d

Initially, 50 g Eu₃O₄Cl and 450 g CsBr powder are filled into a molybdenum vaporizer. The materials are simultaneously vaporized so that a white CsBr:EuCl₂ luminophore layer or storage luminophore layer is produced. This is an example of an Eu-oxyhalogenide and cesium bromide.

### EXAMPLE e

Initially, 12 g Eu₃O₄Br, 3 g Eu₃O₄₁ and 595 g CsBr powder are filled into a molybdenum vaporizer. The materials are simultaneously vaporized to produce a white CsBr:EuBr,I luminophore layer or storage luminophore layer. This is an example of an Eu-oxybromide/halogenide mixture and cesium bromide.

### EXAMPLE f

Initially, 3 g Eu₃04F, 7 g Eu₃O₄Cl and 390 g CsBr powder are filled into a molybdenum vaporizer. The materials are simultaneously vaporized so that a white CsBr:EuF,Cl luminophore layer or storage luminophore layer is produced. This is an example of an Eu-oxyhalogenide/halogenide mixture and a cesium halogenide.

### EXAMPLE g

Initially, 5 g Eu₃O₄Br, 150 g CsCl and 390 g CsBr powder are filled into a molybdenum vaporizer. The materials are simultaneously vaporized to produce a white CsBr/Cl:EuBr₂ luminophore layer or storage luminophore layer. This is an example of an Eu-oxybromide and a cesium bromide/halogenide mixture.

### EXAMPLE h

Initially, 30 g Eu₃O₄Br, 120 g RbBr and 350 g CsBr powder are filled into a molybdenum vaporizer. The materials are heated to simultaneously vaporize to provide a white Rb/CsBr:EuBr₂ luminophore layer or storage luminophore layer. This is an example of an Eu-oxybromide and a cesium/rubidium bromide mixture.

### EXAMPLE i

Initially, 20 g Eu₃04Br, 190 g RbI and 290 g CsBr powder are filled into a molybdenum vaporizer. These materials are heated to simultaneously vaporize and produce a white Rb/CsBr/I:EuBr₂ luminophore layer or storage luminophore layer. This is an example of an Eu-oxybromide and a cesium/rubidium bromide halogenide mixture.

### EXAMPLE j

Initially, 8 g Eu₃O₄I, 12 g Eu₃O₄Cl, 150 g RbCl and 230 g CsBr powder are filled into a molybdenum vaporizer. The materials are heated to simultaneously vaporize and produce a white Rb/CsCl/Br:EuI,Cl luminophore layer or storage luminophore layer. This is an example of an Eu-oxyhalogenide/halogenide mixture and a cesium bromide/rubidium halogenide mixture.

### EXAMPLE k

Initially, 20 g Eu₃O₄I and 480 g RbBr powder are filled into a vaporizer made from molybdenum. The materials are heated to simultaneously vaporize to produce a white RbBr:EuI₂ luminophore layer or storage luminophore layer. This is an example of an Eu-oxyhalogenide and rubidium bromide.

### EXAMPLE l

Initially, 10 g Eu₃O₄Br, 5 g Eu₃O₄F and 385 g RbBr powder are filled into a molybdenum vaporizer. The materials are heated to simultaneously vaporize to produce a white RbBr:EuBr,F luminophore layer or storage luminophore layer. This is an example of an Eu-oxybromide/halogenide mixture and rubidium bromide.

### EXAMPLE m

Initially, 30 g Eu₃O₄I, 20 g Eu₃O₄Cl and 450 g RbBr powder are filled into a vaporizer made from molybdenum. The materials are heated to simultaneously vaporize to produce a white RbBr:EuI,Cl luminophore layer or storage luminophore layer. This is an example of an Eu-oxyhalogenide/halogenide mixture and a rubidium halogenide.

### EXAMPLE n

Initially, 5 g Eu₃O₄Br, 180 g RbI and 415 g RbBr powder are filled into a molybdenum vaporizer. The materials are heated to simultaneously vaporize to produce a white RbBr/I:EuBr₂ luminophore layer or storage luminophore layer. This is an example of an Eu-oxybromide and a rubidium bromide/halogenide mixture.

### EXAMPLE o

Initially, 10 g Eu₃O₄I, 20 g Eu₃O₄F, 165 g RbCl and 305 g RbI powder are filled into a molybdenum vaporizer. The materials are heated to simultaneously vaporize, producing a white RbI/Cl:EuI,F luminophore layer or storage luminophore layer. This is an example of an Eu-oxyhalogenide/halogenide mixture and a rubidium bromide/halogenide mixture.

Although various minor modifications may be suggested by those versed in the art, it should be understood that we wish to embody within the scope of the patent granted hereon all such modifications as reasonably and properly come within the scope of our contribution to the art.

We claim:

1. A method for vapor-depositing a layer of a needle-shaped x-ray luminophore with at least one alkali metal on a carrier, said method comprising providing a carrier, simultaneously vaporizing a mixture of at least one europium(III) oxyhalogenide with at least one alkali halogenide and vapor-depositing the vapor on the carrier.

2. A method according to claim 1, wherein the step of simultaneously vaporizing utilizes a molybdenum vaporizer.

3. A method according to claim 1, wherein the simultaneously co-vaporization of the alkali halogenide with the europium(III) oxyhalogenide, the ratio of the Eu concentration of the alkali halogenide layer in the proximity of the substrate to the Eu concentration of the alkali halogenide layer in the proximity of the surface can be reproduced between a factor of 0.4 and 1.2.

4. A method according to claim 3, wherein the concentration is reproduced between a factor of 0.6 and 0.8.

5. A method according to claim 1, wherein the at least one europium(III) oxyhalogenide has a formula of Eu₃O₄Hal, wherein Hal is at least one halogenide from a group consisting of F, Cl, Br and I.

6. A method according to claim 5, wherein the alkali halogenide comprises at least one metal selected from a group consisting of Na, K, Rb and Cs and at least one halogenide from the group F, Cl, Br and I.

7. A method according to claim 1, wherein the x-ray luminophore occurs according to the following formula:
AB/C:EuD,E
wherein A is an alkali metal from a group consisting of Na, K, Rb and Cs; B and C are at least one halogenide from a group consisting of F, Cl, Br and I; wherein C can equal 0 and D and E are at least one halogenide from a group consisting of F, Cl, Br and I, wherein A, D and/or E can be equal.

8. A method according to claim 7, wherein the depositing of the layer on the carrier forms a storage luminophore plate.
